(19) United States
(12) Patent Application Publication
(10) Pub. No.: US 2006/0125121 A1
(43) Pub. Date: Jun. 15, 2006

(54) Capacitor-less 1T-DRAM cell with Schottky source and drain

(76) Inventors: Chih-Hsin Ko, Fongshan City (TW); Hung-Wei Chen, Hsinchu (TW); Wen-Chin Lee, Hsin-Chu (TW); Min-Hwa Chi, Taipei (TW); Chung-Hu Ke, Taipei (TW)

Correspondence Address: SLATER & MATSIL, L.L.P., 17950 PRESTON ROAD, SUITE 1000, DALLAS, TX, 75252, US

(21) Appl. No.: 11/081,416

(22) Filed: Mar. 16, 2005

Related U.S. Application Data
(60) Provisional application No. 60/636,148, filed on Dec. 15, 2004.

(51) Int. Cl. H01L 31/109

(52) U.S. Cl. 257/900

(57) ABSTRACT

A tunneling injection based Schottky source/drain memory cell comprising: a first semiconductor layer with a first conductivity type overlying an insulating layer, wherein the first semiconductor acts as a body region; a gate dielectric overlying the semiconductor layer; a gate electrode overlying the gate dielectric; a pair of spacers on sides of the gate electrodes; and a first Schottky barrier junction formed on a source region and a second Schottky barrier junction formed on a drain region on opposing sides of the body region. The source and the regions have an overlapping portion with the gate electrode and length of overlapping portion is preferably greater than about 5 Å. Interfacial layers are formed between the first and the second Schottky barrier regions.

This application claims the benefit of U.S. Provisional Application No. 60/636,148, filed on Dec. 15, 2004, entitled “Capacitor-less 1T-DRAM Cell with Schottky Source and Drain,” which application is hereby incorporated herein by reference.

### TECHNICAL FIELD

This invention relates generally to dynamic random access memories, and more specifically to capacitor-less one transistor dynamic random access memory cells having Schottky source and drains.

### BACKGROUND

Embedded dynamic random access memory (DRAM) has great advantages for System-On-Chip (SOC) applications in chip functionality, chip size and bandwidth. However, additional masking steps (typically 5 to 8 steps) are typically needed if common DRAM cells, such as one-transistor and one stack or deep trench capacitor, are to be integrated into standard logic CMOS flows, resulting in additional costs of up to 25%. Fortunately, the recently developed capacitor-less one-transistor DRAM (1T-DRAM) cell offers superior advantages for embedded DRAM or stand-along applications due to its small cell size and full CMOS compatibility.

The capacitor-less 1T-DRAM fabricated on SOI is a MOS transistor with the floating body serving as a storage of signal charge representing logic states “1” or “0.” Most capacitor-less 1T-DRAM cells utilize impact ionization current for write operations. A higher writing speed requires an increase in impact ionization current. However, an increase of impact ionization current degrades device reliability due to hot carriers being injected into the gate dielectric.

Write operation of capacitor-less 1T-DRAM cells can be based on gate-induced drain leakage (GIDL) current. FIG. 1 illustrates a 1T-DRAM that is an nMOSFET with a silicon-on-insulator (SOI) structure. Source 8 and drain 10 are semiconductor materials and overlap with the gate electrode 14. A floating body 6 is formed between source 8, drain 10, dielectric 12 and insulator 4. The writing of a logic “1” operation is performed by biasing drain voltage V_{d} to a small positive voltage (about 0.2V to 0.6V) and gate voltage V_{g} to a greater negative voltage (about −3.5V to −1V). Holes are generated on the surface of the drain 10 in the gate-drain overlap area by band-to-band tunneling of valence electrons. Holes flow into the floating body 6 as GIDL current and pull the potential of the body 6 up to a level close to the positive drain voltage V_{d}. After removing the gate bias V_{g}, the holes accumulated in the body are gradually discharged through the forward-biased body-to-source junction and the positive potential of the body 6 gradually decreases. Thus, after a retention time, the retained “1” signal needs to be refreshed. On the other hand, writing of a logical “0” operation is performed by biasing drain voltage V_{d} to negative voltage (about −1.5V to −0.5V) and gate voltage V_{g} to a low positive voltage (about 0.5V to 1V). The potential of the floating body 6 is pulled to close to the negative drain voltage V_{d} through the forward-biased body-to-drain junction. After removing bias, the negative body potential also gradually increases due to junction leakage from the reverse biased junctions between body 6 and source 8 or drain 10.

Reading of the memory cell is performed by measuring the channel current with bias voltages applied, for example, gate voltage V_{g} at about 0.8V, and drain voltage V_{d} at about 0.2V. The current magnitude is modulated by the body potential and indicates logic “1” or “0” stored.

The previously discussed capacitor-less 1T-DRAM cells have serious drawbacks, mainly in the write operation. Firstly, the writing operation based on impact ionization will generate hot carriers and degrade device reliability such as Vₜ stability and gate-oxide lifetime. If a faster writing operation is desired, there will be higher impact ionization current and more hot carriers generated and thus the device will be degraded more rapidly. Secondly, the writing operation based on GIDL is typically very slow and the gate bias must be pushed to −3.5v to obtain write “1” speed in the nanosecond range. Since standard CMOS processes minimize GIDL, extra processing may be required for maximizing GIDL for the capacitor-less 1T-DRAM cell. Such extra processing includes steps such as removing spacers and LDD implants. This involves higher costs and is incompatible with the standard CMOS flow. Thirdly, the total voltage drop across the gate and drain is limited by the gate-oxide thickness. For example, for a 90 nm device, the gate oxide is about 20 Å and the maximum voltage that can be applied is lower than about 2V. Thus, the higher bias voltage for faster writing operation for both ionization and GIDL mechanism requires a thicker gate oxide and results in scaling difficulty.

Therefore, there is a need for a capacitor-less 1T-DRAM for 65 nm technology and beyond that overcomes the shortcomings of the prior art.

### SUMMARY OF THE INVENTION

The preferred embodiments of the present invention present a capacitor-less 1T-DRAM cell and a method of forming same.

The capacitor-less 1T-DRAM cell is based on a Schottky source/drain (S/D) MOSFET on SOI and the fast writing operation is based on tunneling injection over Schottky barrier. The height of the Schottky barrier can be lowered through implanting. As a result, there are no hot carriers generated degrading device reliability and no high voltage is applied across the gate oxide. The preferred fabrication method is fully compatible with standard CMOS fabrication process.

In accordance with a preferred embodiment of the present invention, a tunneling injection based Schottky source/drain memory cell comprises: a first semiconductor layer with a first conductivity type overlying an insulating layer, wherein the first semiconductor layer acts as a body region; a gate dielectric overlying the first semiconductor layer; a gate electrode overlying the gate dielectric; a pair of spacers on sides of the gate electrodes; a first Schottky barrier junction formed on a source region and a second Schottky barrier junction formed on a drain region on opposing sides of the body region, wherein the first and the second Schottky barriers are formed between the body region and the source/drain suicides. The source and drain regions have overlap portions with the gate electrode. The length of overlapping portion is preferably greater than about 5 Å.

In accordance with another aspect of the present invention, a second semiconductor layer, also called an interfacial layer is formed between the first semiconductor layer and the source/drain silicides. The second semiconductor layer can be of different conductivity types in the source and drain regions. It is preferably formed by tilt implanting into the source and drain regions. The second semiconductor layer preferably has lower band gap and higher dopant concentrations than the first semiconductor layer in order to lower the Schottky barrier heights.

In accordance with another aspect of the present invention, the metal or metal silicides of the Schottky barriers can have different barrier heights for electrons and holes. By adjusting the barrier heights, the memory cells are made suitable for various applications.

Reading operation is performed by measuring drain current I_{d} with gate voltage V_{g} and drain voltage V_{d} biased to low positive voltages and source voltage Vₛ kept at 0V. The magnitude of the drain current I_{d} reflects the logic “1” or “0” stored.

The preferred embodiments of the present invention have several advantageous features. Firstly, the carrier tunneling injection does not generate hot carriers during writing operation, so that device reliability is enhanced. Secondly, the Schottky S/D MOSFET on SOI has better scaling capability for suppressing short channel effects. Thus the new cell is more suitable for continuous scaling for future 45 nm node and beyond. Thirdly, the fabrication method of the Schottky S/D cell is CMOS compatible. Thus conventional CMOS can be fabricated together with the preferred embodiments of the present invention on the same chip.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a cross sectional view of a conventional 1T-DRAM cell formed with a silicon-on-insulator structure;

FIGS. 2 through 5 are cross-sectional views of intermediate stages in the manufacture of a 1T-DRAM cell embodiment; and

FIG. 6 illustrates drain currents as a function of gate voltage for a typical Schottky source and drain MOSFET.

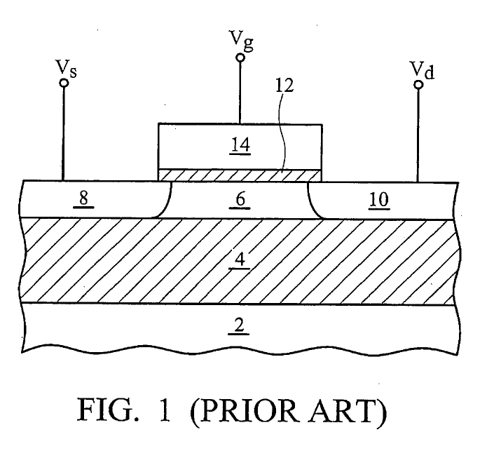

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel structure having Schottky source/drain (S/D) and the method of forming such is presented. The intermediated stages of manufacturing a preferred embodiment of the present invention are illustrated. The variations and operation of the preferred embodiments are then discussed. Throughout the various views and illustrative embodiments of the present invention, like reference numbers are used to designate like elements.

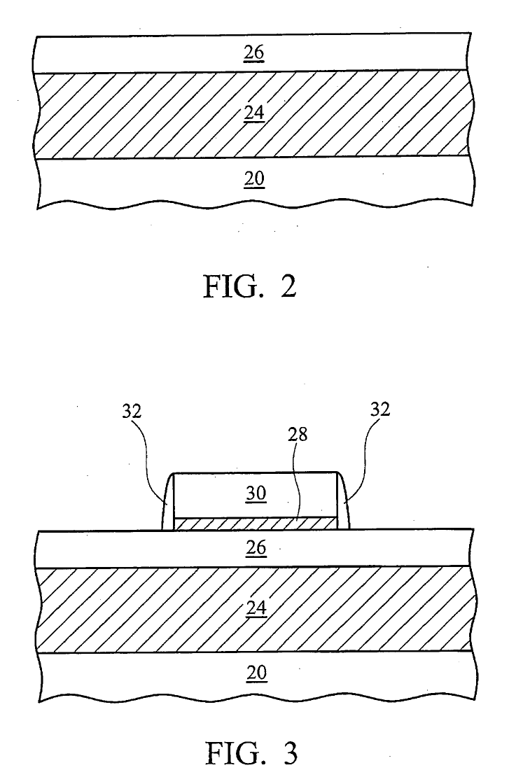

FIGS. 2 through 5 illustrate intermediate steps in the manufacture of a preferred embodiment of a Schottky S/D DRAM of the present invention. FIG. 2 illustrates a silicon-on-insulator structure. An insulator 24 is formed on a substrate 20. A semiconductor 26 is formed on the insulator 24, thereby forming a commonly known silicon-on-insulator (SOI) structure. Preferably, the semiconductor 26 has a thickness of between about 50 Å and 500 Å and is lightly doped. The semiconductor 26 can be doped with either p-type or n-type dopants. In the preferred embodiment, the semiconductor 26 comprises SiGe. SiGe is preferred since it has smaller band gap and therefore leads to stronger tunneling injection, lower Schottky barrier to holes and electrons (depending on the percentage of Ge), higher carrier mobility for fast write/read cycle applications, and higher read current. In alternative embodiments, semiconductor 26 may comprise silicon, germanium, carbon and combinations thereof.

FIG. 3 illustrates the formation of a gate structure. A gate dielectric layer 28 is first formed on semiconductor 26, followed by a gate electrode layer 30. These layers are then patterned and etched to form the gate electrode 30 and gate dielectric 28. The gate dielectric 28 can be formed of oxides, nitrogen containing material or high-k materials. The gate electrode 30 preferably comprises polysilicon, metal silicides or metal. Preferably, the direction of the gate structure is such laid out such that a subsequently formed device has a channel in the 110 or 100 direction.

A hard mask (not shown) is optionally formed on the gate electrode 30 to protect it from being implanted in subsequent steps. FIG. 3 also illustrates spacers 32 formed along the sidewalls of the gate dielectric 28 and gate electrode 30. Spacers 32 serve as self-aligning masks for subsequent source and drain Schottky barrier formation steps and help in reducing implant damage to the gate dielectric 28 and gate electrode 30, as described in detail below.

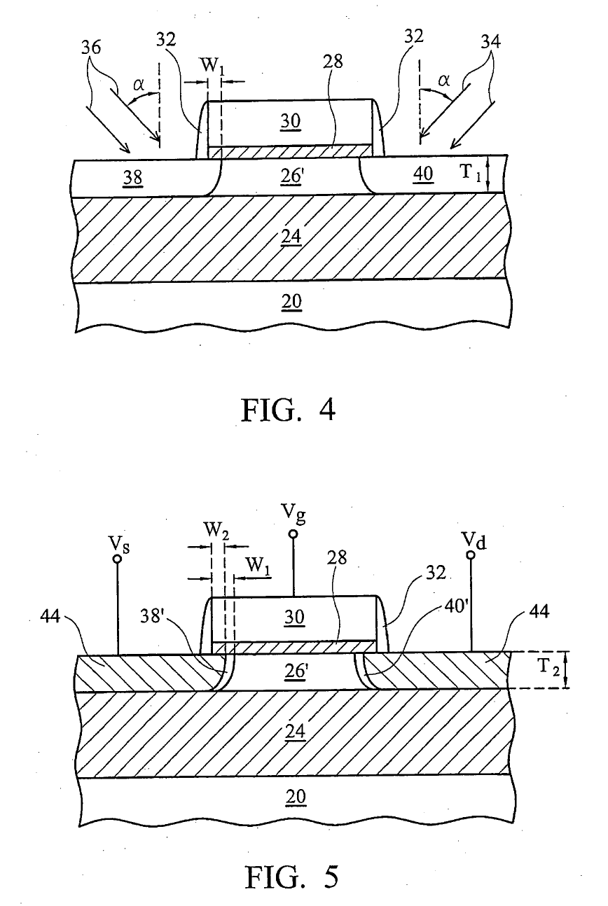

FIG. 4 illustrates implant regions 38 and 40. Since a Schottky barrier is formed between a (Schottky) metal and a semiconductor and the Schottky height is a function of the band gap of the semiconductor, it is preferred that an interfacial layer having a lower band gap and higher concentration than the semiconductor 26 is formed adjacent to the (Schottky) metal in order to lower the height of the Schottky barrier. It is also preferred that the height of the Schottky barriers is less than about 0.8 eV. The implant regions 38 and 40 may be formed by tilt implanting dopants from both the source and drain sides. The implants are symbolized by arrows 36, which are tilted from the source side, and arrows 34, which are tilted from the drain side. No mask is required for the tilt implants. The interfacial layers have a depth T₁ of less than 300 Å. FIG. 4 illustrates implant regions 38 and 40 as extending to the insulator 24. However, the depth T₁ may be less than the thickness of the semiconductor 26. By using spacers 32 as implant masks, the implant regions 38 and 40 can slightly exceed the boundary of gate electrode 30, forming overlap regions between interfacial layers 38/40 and gate electrode 30.

FIG. 5 illustrate the formation of silicide regions 44. To form a silicide layer, a metal layer is formed by first depositing a thin layer of metal, such as cobalt, nickel, erbium, tungsten, titanium, platinum or the like, over the device. The device is then annealed to form a silicide between the deposited metal and the underlying exposed silicon regions. After silicidation, the silicide regions 44 preferably extend beyond the gate electrode boundary by a width W₂ of greater than about 5 Å so that overlap regions are formed. The overlap regions between source/drain and gate electrode improve carrier injection during the write operation since the gate bias modulates the Schottky barrier height and shape in the overlap regions. The thickness T₂ is preferably less than about 300 Å.

The un-silicided portions of the implant region 38 and 40 form thin interfacial layers 38′ and 40′, respectively. A source having an n-type interfacial layer at a mid-gap Schottky barrier will reduce barrier height and width with respect to electrons. A drain having a p-type interfacial layer at a mid-gap Schottky barrier will reduce barrier height and width with respect to holes. Referring back to FIG. 4, on the source side, the interfacial layer 38 can be doped with n-type dopants, symbolized by arrows 36. On the drain side, the interfacial layer 40 can be doped with p-type dopants, symbolized by arrows 34. As a trade-off, the retention time of electrons and holes are also reduced due to lower barrier and thinner width. Such Schottky junctions with interfacial doping layers 38 and 40 are particularly suitable for “fast” 1T-DRAM, where fast and frequent write/read cycles instead of retention time are the most important.

Preferably, the silicidation step consumes the silicon in source and drain regions and the resulting silicide regions 44 extend to the insulator 24, as shown in FIG. 5. A Schottky barrier is formed between source silicide 44 and semiconductor 26 or 38, depending on which material is adjacent the source silicide 44. Similarly, a Schottky barrier is formed between drain silicide 44 and semiconductor 26 or 40. The insulator 24, Schottky barriers and gate dielectric 28 therefore isolate the semiconductor 26 into a floating body 26′. The floating body 26′ having charges stored therein is used to represent logic states “1” or “0.”

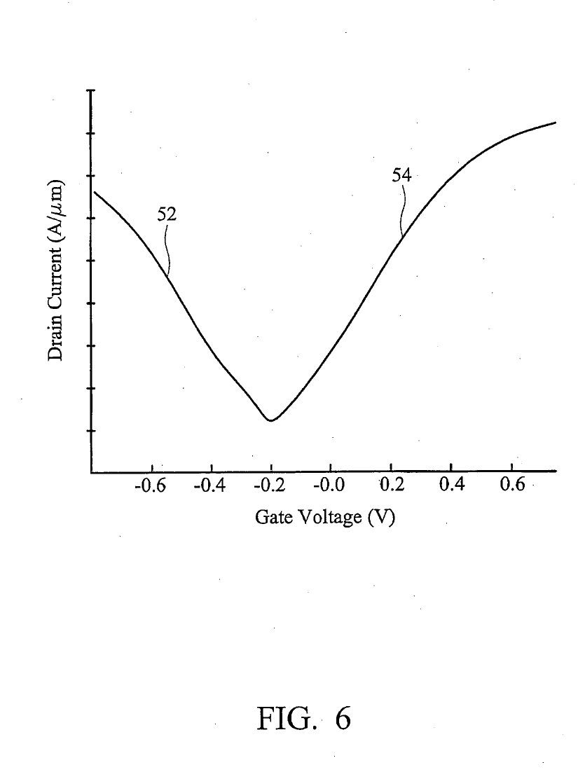

FIG. 6 illustrates drain current I_{d} as a function of gate voltage V_{g} in a typical Schottky S/D MOSFET. Two mechanisms are likely involved. When V_{g} is greater than 0V, the drain current 54 is mainly due to electron tunneling injection from the source and is often referred to as n-channel operation. When V_{g} is smaller than 0V, the drain current 52 is mainly due to hole injection from the drain such as GIDL and is often referred to as p-channel operation. These mechanisms are utilized in the operation of the preferred embodiments of the present invention.

The Schottky S/D DRAM cell formed in the previously described steps have three basic operations, writing “0”, writing “1”, and reading. Referring back to FIG. 5, bias voltages are applied in order to perform writing and reading operations. A writing “1” operation is performed by biasing gate voltage V_{g} to a negative voltage (for example, −1V) and setting source and drain voltages to 0V. Holes are injected from the source and drain 44 by tunneling through the Schottky barrier into the floating body 26. This results in positive floating body potential after writing “1” and setting V_{g} back to 0V. The stored holes in the floating body will result in greater drain current I_{d} during reading operation. This “body” effect of Schottky S/D MOSFET is similar to a conventional p-n junction MOSFET. The stored holes will gradually leak away through Schottky junctions. After a retention time, the cell needs to be refreshed.

A writing “0” operation is performed by biasing the gate voltage V_{g} to a positive voltage (for example, 1V) and setting source and drain voltages to 0V. Electrons are injected from source and drain silicide regions 44 by tunneling through the Schottky barrier into the floating body 26. This results in negative floating body potential after writing “0” and setting gate voltage V_{g} back to 0V. The stored electrons in the floating body will result in smaller drain current I_{d} during reading operation. Similarly, stored electrons will gradually leak away through Schottky junctions. After a retention time, the cell needs to be refreshed.

Another exemplary operation of writing can be performed with different voltages applied from the previous example. A writing “1” operation can be performed by biasing V_{g} to a negative voltage such as −1V, V_{d} to a positive voltage and keeping Vₛ floating or grounded. Holes are injected from the drain by tunneling through the Schottky barrier into the floating body. This results in positive floating body potential after writing “1” and setting V_{g} back to 0V.

A write “0” operation can be performed by biasing V_{g} to a positive voltage such as 1V, V_{d} to a positive voltage and keeping Vₛ to ground. Electrons are injected from source by tunneling through the Schottky barrier into the floating body and result in negative floating body potential after writing “0” and setting V_{g} back to 0V.

The reading operation is performed by measuring drain current I_{d} with gate voltage V_{g} and drain voltage V_{d} biased to small positive voltages (for example, V_{g} and V_{d} both at about 0.5V) and source voltage Vₛ kept at 0V. The floating-body potential modulates I_{d}. The amplitudes of the drain current I_{d} represents the stored “1” or “0.” An advantage of the preferred embodiments of the present invention is that the reading operation is not destructive as in conventional DRAM, and there is no need to have a “writing back” operation.

In order to have equally fast writing “1” and “0” operations, cell structure may be designed to have a mid-gap symmetrical Schottky barrier. Certain factors have to be taken into design considerations. Equally fast operations of writing “1” and “0” are highly desirable. Therefore Schottky barriers with respect to both electrons and holes are critical design parameters. This calls for equal barrier heights and shapes to electrons and holes for tunneling through their respective Schottky barriers during writing operations. There are mid-gap Schottky materials readily available for such needs, for example, silicides such as NiSi, CoSi and TiSi, metals/metal nitrides such as Ta, TaN, and WN. The doping of the floating body also needs to be light so that the Fermi-level is in the middle of the band-gap. The retention times for both electron and hole are also preferred to be equally long. A good indication of whether electron and hole injections are equally fast is whether the I_{d}-V_{g} curve referred in FIG. 6 is symmetrical or not.

Asymmetrical Schottky barriers can also be used for equally fast writing “1” and “0” operations. There are materials available with asymmetrical Schottky barriers, e.g. ErSi has barrier height of 0.82 eV to holes and 0.28 eV to electrons. By using these materials, electron retention time is short and writing “0” is fast. Conversely, hole retention time is long and writing “1” is slow. Such an asymmetrical barrier can be modified to achieve equally fast writing “1” and “0.” By adjusting gate bias and carefully selecting corresponding V_{g}, similar levels of I_{d}s can be obtained from the hole injection side and electron injection side in the I_{d}-V_{g} curve referred to in FIG. 6. However, in this case, the electron retention time is shorter than the hole retention time, and thus this type of memory is suitable for writing “1” only memory application. Similarly, PtSi has Schottky barriers 0.23 eV to holes and 0.87 eV to electrons, and it can be used for writing “0” only memory, where electron retention time needs to be long.

There are Schottky barrier materials such as certain metals and suicides having low barriers to electrons. For example, ErSi₂ has 0.28 eV barrier height to electrons. Therefore the electron injection or writing “0” operation is fast but writing “1” operation is slow. This type of cells are suitable for writing-“0”-only page-mode data storage applications, where all bits of “1”s simply have their floating body discharged to 0V without being refreshed. Certainly, the read current difference between bit “0” and “1” may be smaller than the current difference between the fully written bit “0” and “1.” Conversely, if PtSi is used at the source and drain as Schottky material, the Schottky barrier to holes is about 0.23 eV, and the cell is suitable for writing “1” only page-mode data storage applications.

The proposed capacitor-less 1T-DRAM based on Schottky S/D MOSFET has several advantageous features. Firstly, the carrier tunneling injection does not generate hot carriers during writing operation so that device reliability is enhanced. Secondly, the Schottky S/D MOSFET on SOI has better scaling capability for suppressing short channel effect, thus the new cell is more suitable for continuous scaling for 45 nm node and beyond. Thirdly, the fabrication method of the Schottky S/D cell is CMOS compatible so that conventional CMOS such as logic operation circuit can be fabricated on the same chip as the preferred embodiments. The concept of the capacitor-less 1T-DRAM cell of the present invention can be extended to form FinFET or double-gate MOSFET with Schottky S/D.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A memory cell comprising:
a first semiconductor layer with a first conductivity type overlying an insulating layer wherein the first semiconductor layer acts as a body region;
a gate dielectric overlying the first semiconductor layer;
a gate electrode overlying the gate dielectric;
a pair of spacers on sides of the gate electrode; and
a first Schottky barrier junction formed on a source region and a second Schottky barrier junction formed on a drain region on opposing sides of the body region wherein the first and second Schottky barriers are under the gate electrode.

2. The memory cell of claim 1 wherein there exists a net concentration of carriers of the first-type conductivity in the body region, the net concentration resulting from gate induced drain leakage like (GIDL-like) current and flow of carriers of the drain through the second Schottky barrier junction and confined by the first Schottky barrier junction.

3. The memory cell of claim 1 wherein the thickness of the first semiconductor layer is greater than about 50 Å.

4. The memory cell of claim 1 wherein the first semiconductor layer comprises a material selected from the group consisting essentially of silicon, germanium, carbon, and combinations thereof.

5. The memory cell of claim 1 wherein the source and drain regions comprise a refractory metal or a metal compound.

6. The memory cell of claim 5 wherein the source and drain regions comprise a metal silicide selected from the group consisting essentially of ErSi, CoSi, NiSi, TiSi, WSi, PtSi and combinations thereof.

7. The memory cell of claim 1 wherein the first and the second Schottky barriers have a junction height of smaller than about 0.8 eV.

8. The memory cell of claim 1 further comprising a second semiconductor layer between the source and the first semiconductor layer and a third semiconductor layer between the drain and the first semiconductor layer.

9. The memory cell of claim 8 wherein the second and the third semiconductor layers comprise a material selected from the group consisting of silicon, germanium, carbon, and combinations thereof.

10. The memory cell of claim 8 wherein the second semiconductor layer is doped with a second conductivity type dopant and the third semiconductor is doped with a third conductivity type dopant, wherein the second and third conductivity types are selected from the group consisting of p-type and n-type.

11. The memory cell of claim 8 wherein the second and third semiconductor layers have a thickness of less than about 300 Å.

12. The memory cell of claim 1 wherein the source region and drain regions overlap with the gate electrode.

13. The memory cell of claim 12 wherein the overlap regions have a width of greater than about 5 Å.

14. The memory cell of claim 1 wherein a channel is formed between the source region and the drain region and wherein the channel is in the 110 or 100 direction.

15. A memory cell comprising:
a first semiconductor layer with a first conductivity type overlying an insulating layer wherein the first semiconductor acts as a body region;
a gate dielectric overlying the semiconductor layer;
a gate electrode overlying the gate dielectric;
a pair of spacers on sides of the gate electrodes;
a first Schottky barrier junction formed on a source region and a second Schottky barrier junction formed on a drain region on opposing sides of the body region;
wherein the source region and the drain region overlap with the gate electrode and wherein the overlap regions have a width of greater than about 5 Å; and
wherein the first Schottky barrier junction region is adjacent to a second semiconductor layer and the second Schottky barrier junction region is adjacent to a third semiconductor layer.

16. The memory cell of claim 15 wherein the thickness of the first semiconductor layer is greater than about 50 Å.

17. The memory cell of claim 15 wherein the source and drain regions comprise a metal silicide selected from the group consisting essentially of ErSi, CoSi, NiSi, TiSi, WSi, PtSi and combinations thereof.

18. The memory cell of claim 15 wherein the first and the second Schottky barriers have a junction height of smaller than about 0.8 eV.

19. The memory cell of claim 15 wherein the second semiconductor layer is doped with a second conductivity type dopant and the third semiconductor is doped with a third conductivity type dopant, wherein the second and the third conductivity types are selected from the group consisting of p type and n type.

20. The memory cell of claim 15 wherein the second and the third semiconductor layers have a thickness of less than about 300 Å.

21. A method of forming a memory cell, the method comprising:
providing a first semiconductor layer of a first conductivity type overlying an insulating layer wherein the first semiconductor layer acts as a body region;
forming a gate dielectric over the semiconductor layer;
forming a gate electrode over the gate dielectric;
forming a pair of spacers on sides of the gate electrodes;
forming a first Schottky barrier junction in a source region and a second Schottky barrier junction in a drain region on opposing sides of the body region; wherein the first and the second Schottky barriers are under the gate electrode; and
causing a net concentration of carriers of the first-type conductivity in the body region, the net concentration being resulted from GIDL-like current.

22. The method of claim 21 further comprising s step of forming a second semiconductor layer and a third semiconductor layer, the second semiconductor layer being adjacent to the first Schottky barrier junction and the third semiconductor layer being adjacent to the second Schottky barrier junction.

23. The method of claim 22 wherein the step of forming the second and the third semiconductor layers comprising the steps of:
tilt implanting a second-type dopant from the source side into a region under the gate electrode; and
tilt implanting a third-type dopant from the drain side into a region under the gate electrode.

24. The method of claim 23 wherein the second semiconductor layer is implanted with a second conductivity type dopant and the third semiconductor is implanted with a third conductivity type dopant, wherein the second and third conductivity types are selected from the group consisting of p type and n type.

25. The method of claim 21 wherein the source and the drain regions comprise a refractory metal or a metal compound.

26. The method of claim 21 wherein the source and the drain regions comprise a metal silicide selected from the group consisting essentially of ErSi, CoSi, NiSi, TiSi, WSi, PtSi and combinations thereof.
